(19) United States
(12) Patent Application Publication
(10) Pub. No.: US 2007/0152133 A1
(43) Pub. Date: Jul. 5, 2007

(54) Image sensor array with ferroelectric elements and method therefor

(75) Inventors: Fan He, Gurnee, IL (US); Carl L. Shurboff, Grayslake, IL (US)

Correspondence Address: VEDDER PRICE KAUFMAN & KAMMHOLZ, 222 N. LASALLE STREET, CHICAGO, IL, 60601, US

(73) Assignee: Motorola, Inc., Schaumburg, IL (US)

(21) Appl. No.: 11/323,097

(22) Filed: Dec. 30, 2005

(51) Int. Cl. H01L 27/00

(52) U.S. Cl. 250/208.1

(57) ABSTRACT

A light sensing circuit (400) and image sensor array includes at least one light sensing element (402), such as a photodiode, and at least one ferroelectric element (404), such as a CMOS ferroelectric gate field effect transistor (FET), that is operatively coupled to the light sensing element to form a photo cell. The ferroelectric element provides charge storage as a non-volatile analog memory element. As such, a type of photo cell serves as a ferroelectric memory that can store the charge from the light sensing element and be programmed to provide electronic shutter operation.

### FIELD OF THE INVENTION

The invention relates generally to light sensing circuits and image sensor arrays and more particularly to light sensing circuits and image sensor arrays that employ electronic global shuttering.

### BACKGROUND

Image capture devices such as cell phone cameras, camcorders, and other suitable devices usually have high resolution image sensors. Due to the longer read out time of, for example, charge couple device (CCD) image sensors and CMOS image sensors, global shutters are desired to expose the entire image sensor array simultaneously). Known camera phones use electronic global shutters rather than mechanical camera shutters. Using electronic global shutters with conventional CMOS or CCD image sensors, however, results in a significant tradeoff regarding the fill factor of photo cells (e.g., the size of the photo cell area) which can reduce the sensitivity and dynamic range of the image sensor array. For example, the larger the fill factor, the larger of the photo diode or photo gate for a given image sensor pixel size. A fill factor of 0.4 means that 40% of the pixel area is photo diode or photo gate. For example, the larger the fill factor, the fewer number of photo cells that can be located in a given area of an image sensor array that is fabricated as an integrated circuit. For example, the size of a photodiode along with accompanying logic can vary depending upon the design of a photo cell.

With the larger form factor of a photo cell, the sensitivity and dynamic range of the image sensors can be affected. Adding global electronic shutter function can affect the sensitivity and dynamic range of the image sensors. For example, for a fixed photo cell size the size of the photodiode may have to be reduced in order to accommodate more transistors and/or diodes used to retain the light energy received by the photodiode and to provide electronic shutter control. Because of the size limit of handheld devices, such as cell phones, global shutter image sensors attempt to achieve high resolution with smaller pixel sizes. Because the dynamic range and sensitivity decrease with pixel size, conventional CMOS image sensors can experience performance degradation at higher resolutions.

Foveon true RGB image sensors attempt to resolve the resolution limit issue associated with Bayer pattern image sensors, but Foveon image sensors typically need 15 transistors per pixel to realize electronic global shutter operation which is not feasible with the limited size of the image sensor due to the low pixel fill factor required for smaller handheld devices.

Examples of some prior art photo cells, also referred to image sensors, are shown in FIGS. 1-3. For example, FIG. 1 which is a single pixel photo cell (here shown to be a black and white pixel) utilizes three transistors M1, M2 and M3 in addition to a light sensing element such as a photodiode 10.

In operation, the photodiode 10 is reset to a supply voltage Vdd by turning on transistor M2. After the photodiode is reset, control logic turns off transistor M2. Then, over a suitable integration period, a photo generated charge is accumulated on the photodiode 10, discharging the photodiode from the reset voltage to a lower voltage. To read the pixel value from the bit line 12 after integration, transistor M3 is turned on and the photodiode voltage is buffered through transistor M1 which forms part of a source follower circuit (M1). This photodiode voltage is read out by an analog to digital converter. A drawback of this photocell is that the photodiode 10 may continue discharging during the read out period since the exposure time may not be the same for each pixel in an image sensor array even using a rolling shutter control (e.g., exposing columns or rows sequentially instead of all at a same time).

FIG. 2 illustrates another photo cell or pixel architecture which utilizes four transistors M1, M2, M3 and M4. The photodiode 10 is reset to supply voltage Vdd by turning on the reset transistor M2 and the transfer gate on transistor M1. Also, transistor M4 is momentarily turned on to read the reset level sensed by transistor M3 via bit line 12. The transfer gate on transistor M1 is then switched off and a photo generated charge is stored in the photodiode 10. After a suitable integration period, transistor M2 is turned off so that the parasitic capacitance at the gate of transistor M3 is released from the reset level and allowed to charge based on the charge obtained by the photodiode 10. The transfer gate of transistor M1 is then turned on and all the photo generated charge flows into the capacitance of the gate on transistor M3 and charges to the level of the photodiode. The output of the pixel is then stored via bit line 12.

The two stored pixel values (the reset value and photodiode based value) are subtracted from each other to remove any offsets in the pixel source follower and also any reset noise present on the sense capacitance at the sense node. The pixel does not suffer from noise problems such as may occur when the pixel architecture shown in FIG. 1 is used. The FIG. 2 architecture attempts to fix the problem of the architecture shown in FIG. 1 by isolating the photodiode 10 from the read out circuit using the transfer gate of transistor M1. However, one problem with this architecture is the fill factor; the photodiode sensitivity and dynamic range are reduced due to the smaller fill factor of the photodiode which is caused by the additional circuit area required by the additional transistor. For example, given the increase in the number of transistors required, the size of the photodiode 10 may have to be reduced if the entire circuit is to be kept at the same size as the architecture shown in FIG. 1. In addition, this structure still does not provide electronic global shutter operation.

FIG. 3 illustrates a five transistor architecture that provides electronic global shutter operation. The photodiode 10 is reset by turning on the global reset transistor 14 (M5). The transfer gate 16 (M1) is off, the reset gate 18 (M2) is on, and the supply voltage Vdd is stored in the photodiode 10 when the global reset transistor 14 (M5) is turned off. The reset gate 18 (M2) is turned on to reset the sense capacitance of the gate of the source follower transistor M3. The reset gate 18 (M3) is turned off and the reset value can be read for correlation double sampling purposes via bit line 12. After a suitable integration time, the sense capacitance level at the gate of the source follower transistor M3 is released from the reset level, and the pixel output value at this moment is stored by the sense capacitance M3. The transfer gate 16 (M1) is turned on and all of the photo generated charge flows on the sense capacitor to produce a voltage difference. The output of the pixel is then stored via bit line 12.

The two stored pixel values (the reset value and photodiode based value) are subtracted from each other to remove any offsets in the pixel source follower and also any reset noise present in the sense capacitance similar to the architecture shown in FIG. 2. Although this five transistor architecture fixes problems associated with the architectures shown in FIG. 1 and FIG. 2, the extra transistor and traces required compared to the four transistor architecture, in FIG. 2 for example, cause the photodiode sensitivity and dynamic range to be reduced due to the requirement that the photodiode 10 must be made smaller to fit in the same area. Another problem can be that the storage capacitance has a small leakage which can be very significant during the readout for the high resolution sensors, because the amount of charge being read may be decreased as a function of the leakage. As such, various conventional CMOS image sensor architectures have one or more problems.

Accordingly, there is a need for a light sensing circuit, photo sensor array, or other suitable structure or method that overcomes one or more of the above problems.

### BRIEF DESCRIPTION OF THE DRAWINGS

The invention will be more readily understood in view of the following description when accompanied by the below figures and wherein like reference numerals represent like elements:

FIG. 1 is a schematic illustrating one example of a light sensing circuit, such as a photo cell, as known in the art;

FIG. 2 is a schematic illustrating one example of a light sensing circuit, such as photo cell, as known in the art;

FIG. 3 is a schematic illustrating one example of a light sensing circuit, such as a photo cell, as known in the art;

FIG. 4 is one example of a light sensing circuit, such as a photo cell, in accordance with various embodiments of the invention;

FIG. 5 is a timing diagram that may be used with the light sensing circuit shown in FIG. 4;

FIG. 6 is a flow chart illustrating one example of a method for capturing image information in accordance with various embodiments of the invention;

FIG. 7 is a block diagram illustrating one example of a light sensing circuit in accordance with various embodiments of the invention;

FIG. 8 is a circuit diagram illustrating one example of a light sensing circuit in accordance with various embodiments of the invention;

FIG. 9 is a timing diagram that can be used with the light sensing circuit shown in FIG. 8;

FIG. 10 is a diagram illustrating one example of a photo sensor array in accordance with various embodiments of the invention;

FIG. 11 is a diagram illustrating one example of a photo cell in accordance with various embodiments of the invention;

FIG. 12 is a circuit diagram illustrating one example of a photo cell in accordance with various embodiments of the invention; and

FIG. 13 is a cross sectional view of one example of a CMOS ferroelectric field effect transistor that can be used with various embodiments of the invention.

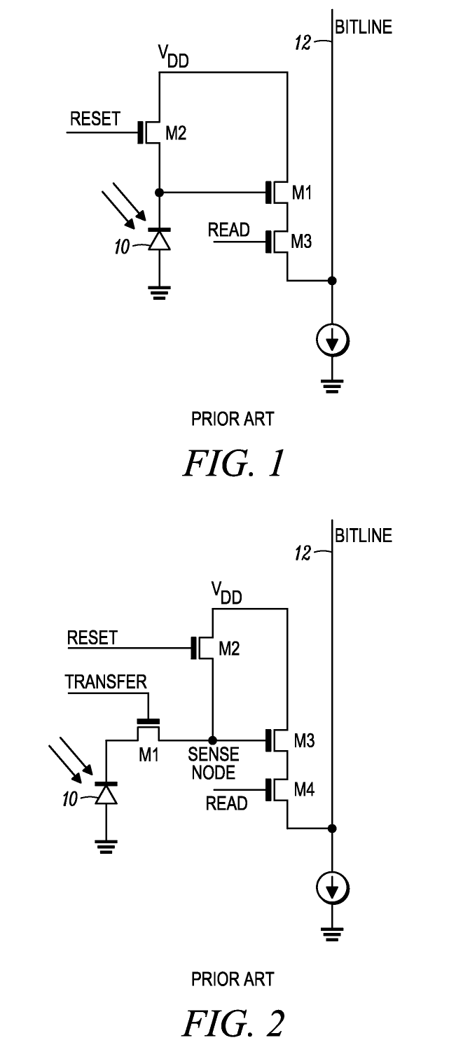

### DETAILED DESCRIPTION OF THE DRAWINGS

Briefly, a light sensing circuit includes at least one light sensing element, such as a photodiode, and at least one ferroelectric element, such as a CMOS ferroelectric gate field effect transistor (FET), that is operatively coupled to the light sensing element to form a photo cell. The ferroelectric element provides charge storage as a non-volatile analog memory element. As such, a type of photo cell serves as a ferroelectric memory that can store the charge from the light sensing element and be programmed to provide electronic shutter operation.

In one example, a one transistor one diode (1T1D) architecture provides a light sensing circuit that includes a diode that is coupled to the light sensing element and the ferroelectric element. The diode is responsive to control information that selectively activates the diode and causes the ferroelectric element to discharge and perform other operations of a photo cell.

In another example, a two transistor (2T) architecture for a light sensing circuit utilizes a light sensing element such as a photodiode, a CMOS ferroelectric element, such as a ferroelectric gate FET, and another field effect transistor to provide a ferroelectric gate photo cell. The photo cells can be combined to make a photo sensor array and may be operatively coupled to suitable control logic that controls the retention and transfer of the obtained photo charge from the ferroelectric element to another memory device, analog to digital converter, or any other suitable logic as desired. The control logic also controls the erasing of the ferroelectric element and resetting of the light sensing element. Among other advantages, the above structure uses fewer transistors and hence can have a larger photodiode form factor thereby increasing the sensitivity of the photo cell relative to other photo cell designs having the same form factor. Other advantages will be recognized by those of ordinary skill in the art.

A method is also disclosed that includes generating retention information, storing a charge representing light energy received by a light sensing element in a ferroelectric element in response to the retention information, generating read information to read the stored charge from the ferroelectric element after storing the charge, and generating erase information to erase the ferroelectric element after reading the stored charge.

FIG. 4 is a schematic diagram illustrating one example of a light sensing circuit 400, such as a photo cell, that includes at least one light sensing element 402, such as a photodiode, and at least one ferroelectric element 404, shown in this example to be a CMOS ferroelectric gate field effect transistor. However, it will be recognized that any suitable light sensing element can be used and any suitable ferroelectric element can be used such as, but not limited to, a capacitor, or any other suitable ferroelectric element. The light sensing circuit 400 may be used, for example, as a photo cell in a photo sensor array in a camera, camcorder or any other suitable device or in any other suitable application.

In this example, the light sensing circuit 400 also includes a ferroelectric element erase and photodiode reset device shown in this example to be a diode 406 that is coupled to both the light sensing element 402 and the ferroelectric element 404. If desired, the light sensing circuit 400 may also include control logic 408 which is used to suitably control the ferroelectric element 404 and diode 406 to cause the light sensing circuit 400 to operate as a photo cell in conventional modes of reset/erase, exposure, retention, and reading. The control logic 408 may be implemented in or suitably programmed processor, in discrete logic or any suitable combination of hardware and software. Although not shown, the control logic may include an A/D for the bit line. In this example, the control logic 408 generates reset/erase control information 410 also referred to as a reset/erase signal that, among other things, selectively activates the diode 406 and causes the ferroelectric element 404 to erase and, in this example, to reset the light sensing element 402. This is also referred to as a one transistor one diode (1T1D) architecture and operates according to Table I.

TABLE I

| | Reset 410 | Vdd 412 | Bit line 414 | Source 416 |
|---|---|---|---|---|
| Erase/reset | −5 V | 5 V | 0 V | 0 V |
| Exposure | 5 V | 5 V | 0 V | 0 V |
| Retention | 0 V | 0 V | High Z | High Z |
| Retention | 0 V | 0 V | High Z | 0 V |
| Retention | 0 V | 0 V | V(Id) | High Z |
| Read | 0 V | 0 V | V(Id) | 0 V |

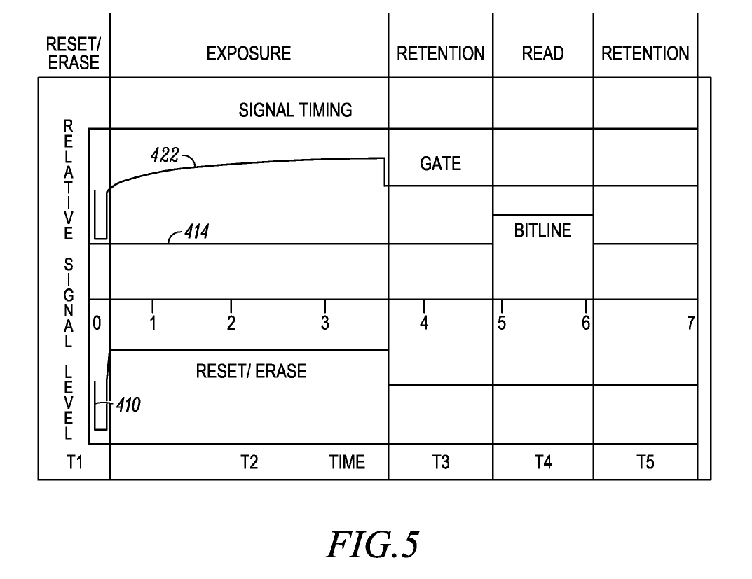

The light sensing element 402 is shown to have a terminal coupled to the control logic 408 which, in this example, may provide light sensing element control information 412. The control logic 408 also produces first control information 414 which is received by a terminal or node of the ferroelectric element 404 and second control information 416 (for example, a source of an N channel ferroelectric FET) that is received by another terminal of the ferroelectric element 404. The control logic 408 can also include the ferroelectric erase and photodiode reset device shown as diode 406 and an analog to digital converter if desired (not shown). The light sensing circuit 400 operates in four states referred to herein as a reset/erase state, an exposure state, a retention state, and a read state. In operation, the control logic 408 generates the various control information 410, 412, 414, 416 according to the timing diagram of FIG. 5 to cause the light sensing circuit 400 to enter the desired state. As shown in this example with the ferroelectric element 404 being a ferroelectric field effect transistor, a gate 422 of the ferroelectric field effect transistor is coupled to a terminal of the photodiode 402 and the diode 406 and has a drain which serves as a bit line from which output information is read which is based on the light sensed by the light sensing element 402. The source of the ferroelectric FET is responsive to the control information 416. As shown in Table I, the control logic 408 causes the ferroelectric element 404 to erase a charge provided by the light sensing element 402, store a charge provided by the light sensing element 402, and output a charge stored by the ferroelectric element 404. As shown in Table I, the circuit can operate in alternate retention states.

Referring also to FIGS. 4, 5 and 6, in operation, the light sensing circuit 400 is responsive to the control logic 408 which erases the ferroelectric element 404 and resets the light sensing element 402 by setting the reset/erase control signal 410 to −5 volts. The ferroelectric element 404 is programmed by setting the reset/erase control signal 410 to 0 volts during time period T1, setting the correct voltages via control information (e.g. signals) 412, 414 and 416 as shown in Table I and during time period T2. During period T3, the control information is controlled to retain or store the charge in the ferroelectric element. The control logic 408 causes the ferroelectric element 404 to be read by setting the reset/erase control signal 410 to 0 volts during time period T4 and connecting the control signal 414 to an output node 420 which serves as a voltage sensing output terminal. As shown in Table I, the control logic 408 may have, for example, a high impedance buffer or other suitable logic to provide a high impedance on the bit line as well as the line that provides control information 416. A non-high impedance connection or pass through connection to read the charge in the ferroelectric element via bit line or signal line 414 is provided as the output terminal 420 shown as V(Id) in Table I. For example, a sense amplifier which measures the current through the ferroelectric element 404 may be switched to the bit line.

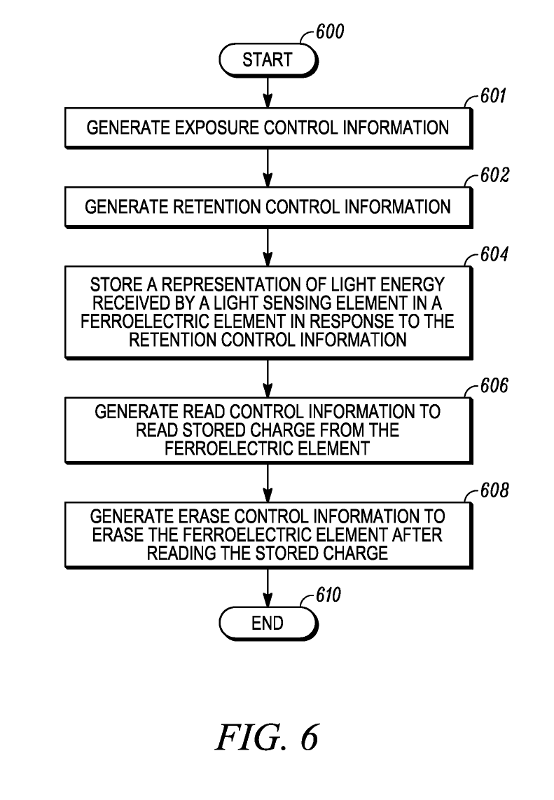

FIG. 6 shows one example of a method for capturing image information that may be carried out, for example, by the light sensing circuit 400 or any other suitable structure. As shown in block 600, the method may include starting by initially erasing the ferroelectric element 404 and resetting the light sensing element 402 as shown, for example, in Table I and time period T1 510 shown in FIG. 5. The method includes generating exposure control information as shown in block 601. As shown in block 602, the method includes generating retention control information such as through the appropriate control signals 412, 414, 410 and 416 as, for example, shown in Table I and time period T2 520 shown in FIG. 5. As shown in block 604, the method includes storing a representation of light energy (e.g., a charge) that is received by the light sensing element in a ferroelectric element in response to the retention control information during time period T3 530 shown in FIG. 5. As shown in block 606, the method includes generating erase control information, such as the appropriate signals using control signals 410, 412, 414, 416 as shown in Table I during time period T4 540 shown in FIG. 5, to read the stored charge from the ferroelectric element. As shown in block 608, the method includes generating erase control information to read the ferroelectric element after reading the charge from the ferroelectric element. The method may then end as shown in block 610 by repeating the process as desired for one or more photo cells either separately or in an array and if desired, applying the same erase/reset signals to all photo cells in a suitable group or array to provide global electronic shutter operation. In addition, each of the respective states may be controlled for any corresponding plurality of ferroelectric elements arranged in a photo sensor array as desired such as generating read signal information for a plurality of ferroelectric elements in a photo sensor array in any suitable number or sequence as desired.

As also shown in FIG. 4, the light energy is stored in the photodiode 402 and a representation thereof in the form of, for example, a voltage level at node 422 is applied to the gate of the ferroelectric element 404 in this example so that the ferroelectric element 404 stores a charge or representation of light energy that is received by the light sensing element 402 over a defined period of time. Also, the charge can be maintained after a read occurs by controlling the circuit to stay in a retention state.

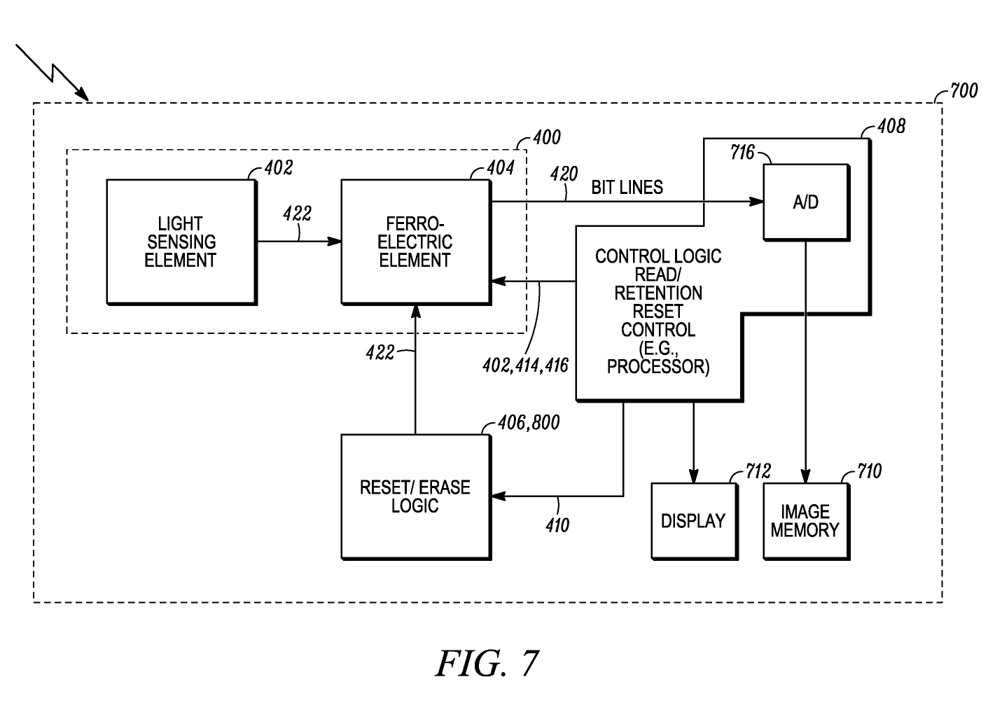

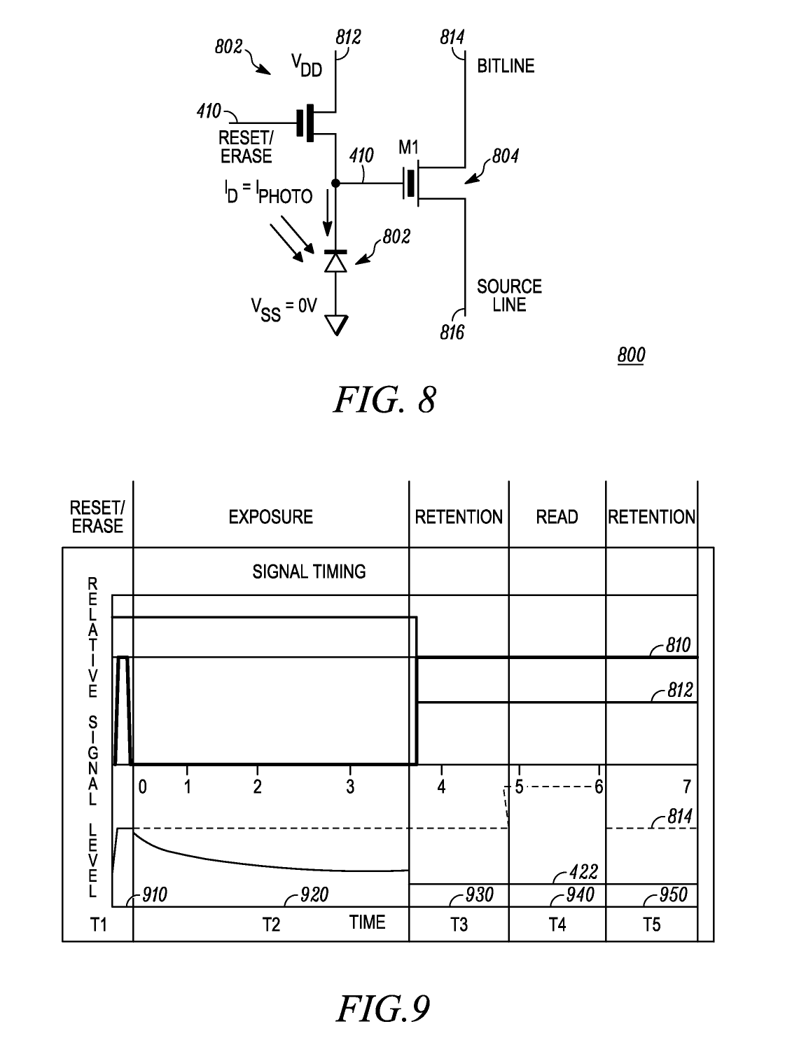

Referring to FIG. 7, a block diagram illustrates one example of a device 700, such as a cell phone, camcorder, or any other suitable device that employs light sensing circuits 400 and/or photo sensing arrays as described herein and reads photo energy from the ferroelectric element 404 into image memory 710 which may then be, for example, displayed on a suitable display 712 as known in the art. The image memory 710 may be, for example, frame buffer memory or any other suitable memory that stores read information from the ferroelectric element 404 that is displayed on display 712. The reset/erase logic 406, 800 may include, for example, a diode 406 or FET device as described previously with respect to FIG. 4 or below with respect to FIG. 8. The control logic 408 also includes an analog to digital converter 716 that converts the read output to a digital value as known in the art. Other suitable devices or combinations of devices may also be used if desired.

FIG. 8 is a schematic illustrating another embodiment of a light sensing circuit in accordance with various embodiments of the invention and may be referred to as a two transistor (2T) ferroelectric gate photo cell. This structure also provides for global electronic shutter operation for a photo sensor array. As shown, the light sensing circuit 800 also includes a field effect transistor 802 which serves as reset/erase logic and as shown has a terminal 822 (e.g., source) coupled to the light sensing element 806 and to a gate of the ferroelectric FET which in this example serves as the ferroelectric element 804. As shown in this example, the cathode of the light emitting element 806 is coupled to the gate of the ferroelectric element 804 whereas in FIG. 4 the anode of the light sensing element was coupled to the gate of the ferroelectric FET. It will also be recognized that the ferroelectric FET and FET 802 are shown as a depletion type devices but that any suitable type may be used such as a P channel type device.

Control logic (not shown) is also used similar to the control logic 408 described with respect to FIG. 4 which controls the light sensing circuit shown in FIG. 8 according to Table II below.

TABLE II

| | Reset 810 | Vdd 812 | Bit line 814 | Source 816 |
|---|---|---|---|---|
| Erase/reset | 5 V | 5 V | 0 V | 0 V |
| Exposure | 0 V | 5 V | 0 V | 0 V |
| Retention | 0 V | 5 V | High Z | High Z |
| Retention | 0 V | 5 V | High Z | 0 V |
| Retention | 0 V | 5 V | V(Id) | High Z |
| Read | 0 V | 0 V | V(Id) | 0 V |

The ferroelectric element 804 is selectively erased through the activation of the field effect transistor 802 and the light emitting element 806 is effectively reset through the selective operation of the field effect transistor 802. The corresponding control logic (not shown) causes the ferroelectric element 804 to erase a charge provided by the light sensing element 806, store a charge provided by the light sensing element 806 and output a charge via the bit line 814 that was stored by the ferroelectric element 804 that may be obtained, for example, during a read cycle of the light sensing circuit 800.

The control logic operates the light sensing circuit 800 according to, for example, the timing diagram shown in FIG. 9. As such, the control logic controls the light sensing circuit to operate in four modes or states including the reset state during time period T1 910, the exposure state during time period T2 920, the data retention state during time period T3 930, and the read state during time period T4 940. An alternative retention state 950 during period T5 is also shown in FIG. 9.

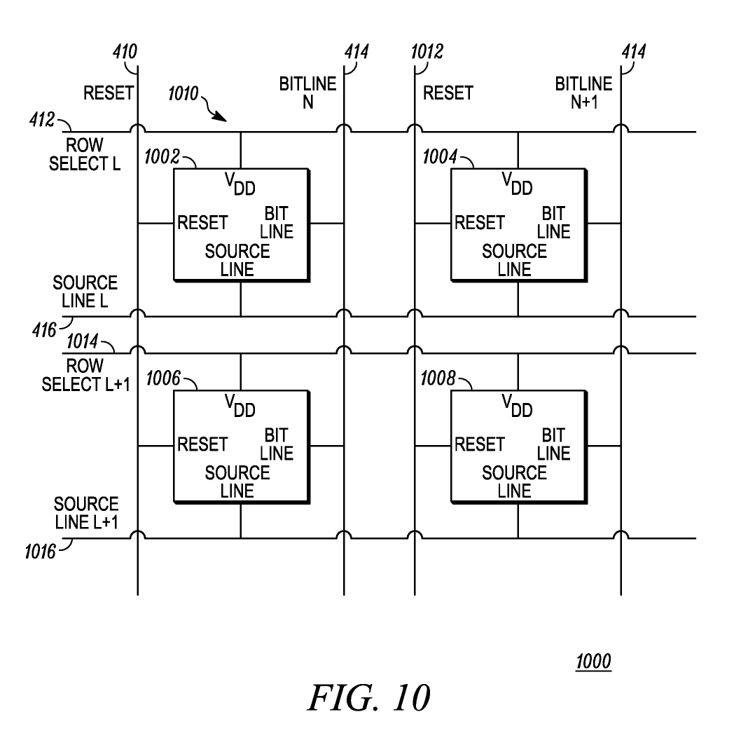

FIG. 10 is a diagram illustrating one example of a photo sensor array 1000 that includes a plurality of ferroelectric element based photo cells 1002, 1004, 1006, 1008 wherein each of the ferroelectric element based photo cells may be one of the photo cells shown, for example, in FIG. 4 or 8. As shown, the photo cells 1002, 1004, 1006, 1008 are arranged in row and columns. However, it will be recognized that any suitable orientation may be used. In the instance where each photo cell is constructed as a one transistor one diode (1T1D) photo cell, for example, as shown in FIG. 4, each photo cell includes a respective light sensing element, a respective ferroelectric element, and a respective diode that is coupled to each light sensing element and corresponding ferroelectric element. As shown in this example, photo cells 1002 and 1006 in the same column such as column 1018, share a reset control line or reset control information line 1010, that communicates control information 410, and photo cells in the same row 1028 share common lines 1012, 1016 for control information 412 and 416. Accordingly, photo cells in the same column are responsive to the same reset control signal information 410 and other photo cells in another column are responsive to other reset control information shown as reset control information 1011. Similarly, photo cells in a same row share common row select control information 1012 (control information 412) and different rows may be responsive to different control signals, such as signal 1013 and 1017 so that various columns and rows can be controlled in a conventional manner.

Accordingly, suitable control logic similar to that described above and with additional features as known in the art to provide control for reset, exposure, retention, and reading states, as required in column and row photo sensor rays, controls each respective ferroelectric photo cell to erase a charge provided by a respective light sensing element, store a charge provided by a respective light sensing element, and output a charge stored by each respective ferroelectric element.

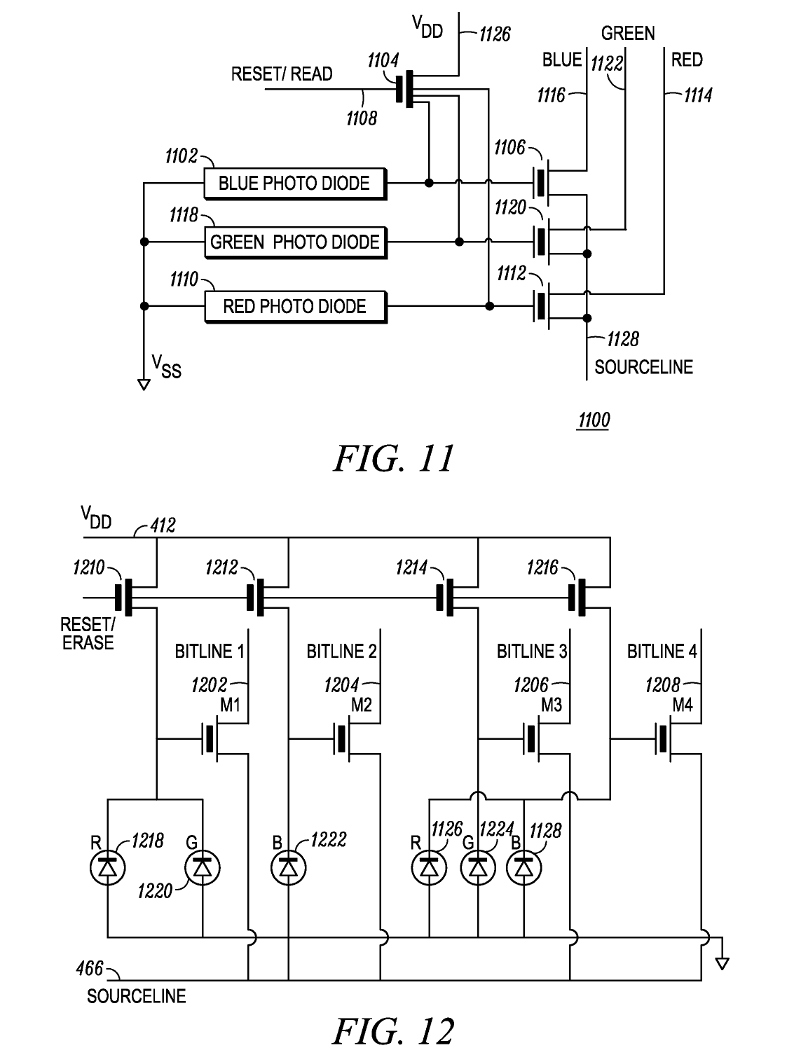

FIG. 11 illustrates one example of a photo sensor array 1100 that may provide, for example, true RGB pixel information. In this example, the photo cell for a pixel includes, for example, a blue photo cell that includes a blue light sensing element 1102, such as a blue photodiode, a corresponding field effect transistor 1104, shown in this diagram functionally as a single field effect transistor with three sources. However, it will be recognized that multiple individual field effect transistors may be used. The field effect transistor 1104 is coupled to the blue light sensing element 1102 and to a corresponding ferroelectric element 1106 shown in this example to be a ferroelectric gate field effect transistor. The field effect transistor 1104 is responsive to reset/read control information signal 1108. The ferroelectric element 1106 outputs a blue output signal 1116. The reset/erase operation happens at the same voltage and the same time and the read operation occurs at a different voltage and a different time.

Similarly, a red photo cell includes a red light sensing element 1110 coupled to a field effect transistor functionally shown as 1104 and to a corresponding ferroelectric element 1112, which produces output information via a drain, shown as a red output signal 1114. A green photo cell includes a green light sensing element 1118, that is operatively coupled to the field effect transistor 1104 and to a corresponding ferroelectric element 1120. The ferroelectric element 1120 outputs green output information 1122 via a drain thereof. A terminal of each of the light sensing elements, in this example shown to be red, green and blue photodiodes, is coupled via a source line 1130 to a Vss, in this case, a ground potential. The reset/read transistor shown as field effect transistor 1104 has a drain coupled to a control line labeled Vdd shown as control line 1126, and each of the ferroelectric elements have a source coupled together and to a source control line 1128.

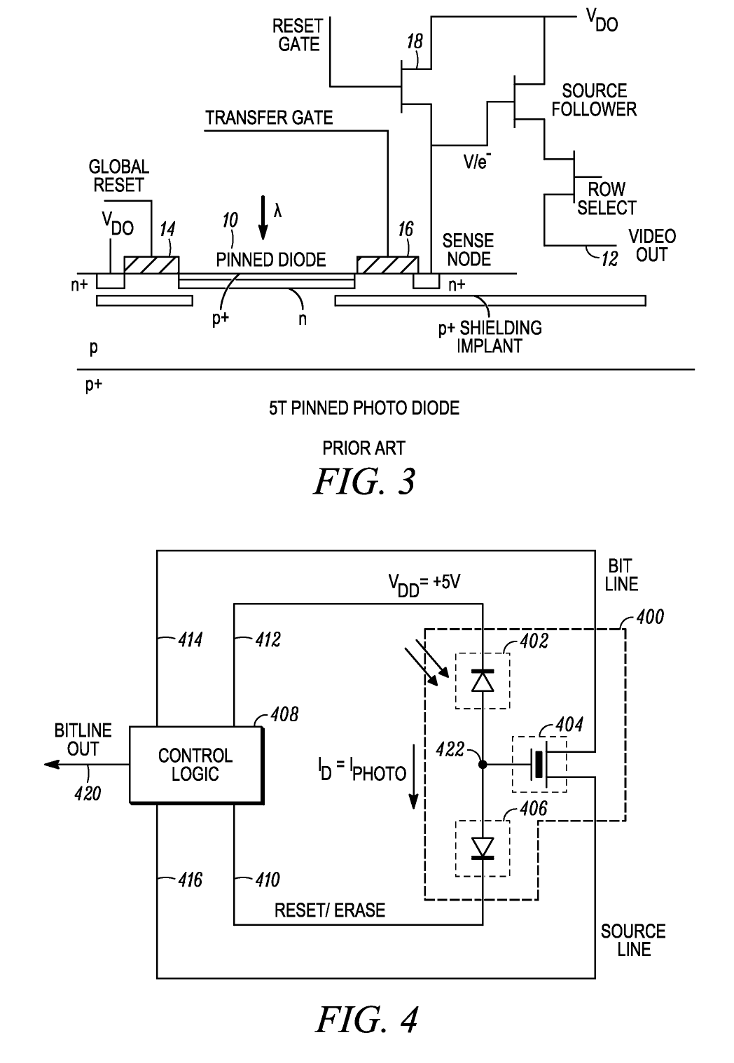

These photo cells may then be duplicated in a suitable arrangement to produce a plurality of pixel cells for a photo sensor array arrangement. As shown above, in contrast to conventional true RGB sensor arrays with global electronic shutter, which may require 15 transistors using the five transistor architecture shown in FIG. 3 for example, the above architecture only requires 6 transistors for a true RGB sensor array with global electronic shutter capabilities. The various control signals may be controlled as described previously.

FIG. 12 illustrates one example of a portion of a photo sensor array configured in a BT656 422 arrangement. As shown, the two transistor architecture of FIG. 8 is applied to a particular color pixel configuration. As shown in this example, each ferroelectric element 1202, 1204, 1206, 1208, each have an output shown as the drain which serves as the respective output bit line 1232, 1234, 1236, 1238 corresponding to each ferroelectric element. Each ferroelectric element is operatively coupled to a field effect transistor used to, for example, reset the photodiodes and erase the respective ferroelectric elements. The field effect transistors are shown as field effect transistors 1210, 1212, 1214 and 1216. A source of each of these field effect transistors is coupled to the gate of each respective ferroelectric element in this example, which is also coupled to cathodes of differing color photodiodes. For example, ferroelectric element 1202 has an input or gate coupled to cathodes of red and green photodiodes 1218 and 1220. Ferroelectric element 1204 has a gate also coupled to the cathode of a blue photodiode 1222. The outputs from the ferroelectric elements 1202 and 1204 are used for one pixel. Another set of RGB photodiodes for another pixel is coupled to the ferroelectric elements 1206 and 1208. For example, ferroelectric element 1206 has a gate coupled to green photodiode 1224, whereas ferroelectric element 1208 has a gate coupled to the cathodes of both red and blue photodiodes 1226 and 1228. The sources of each of the ferroelectric elements 1202 to 1208 are coupled to a control line that provides control information 1217, as previously described, and the drain or a suitable terminal of each field effect transistor 1210, 1212, 1214, 1216 is coupled to receive other control information 1213. The outputs of each of the respective ferroelectric elements 1202, 1204, 1206, 1208 shown as bit lines 1232, 1234, 1236, 1238 are coupled to suitable control logic to provide suitable high impedance paths and connections for retention, read, erase/reset and exposure operations is described, for example, with respect to FIG. 8. Each of the structures described herein may be suitably controlled to provide photo cell operation to store and read out information, as will be recognized by those of ordinary skill in the art. In addition, control logic (not shown) also provides global electronic shutter operation of the photo sensor array, which may be done, as known in the art.

As set forth above, new structures are employed that have some advantages over other photo cell structures in the art. For example, the ferroelectric gate image sensor architecture described above provides electronic global shutter functions with photo cells that employ two transistors or one diode and one transistor. The fill factor associated with such photo cells may be better than conventional three transistor CMOS image sensor architectures, and thus may have better sensitivity and dynamic ranges over four transistor and five transistor CMOS image sensor architectures. The ferroelectric gate image sensor architectures may use higher operation voltages, which can improve the photodiode performance similar to CCD image sensors. Also, the ferroelectric element based photo cell architecture described above is similar to conventional CMOS image sensors regarding the readout method. Accordingly, each pixel or photo cell is individually addressable, which can provide windowing and sub sampling advantages similar to those of conventional CMOS sensors. Accordingly, the ferroelectric element based photo cell architectures described herein may achieve low light performance and dynamic range as CCD image sensors at lower power consumption, particularly in low resolution viewfinder modes for cell phones, as an example.

In addition, the ferroelectric element based photo cell may not have charge leakage issues in contrast with other CMOS structures and therefore may not have fading issues that can be found in the five transistor CMOS architectures. Also, there may be no need for adding light blocking strips to cover the charge storage areas, as can be required with five transistor CMOS architectures. This can further improve the fill factor of the sensor array. The ferroelectric element based photo cells have non-volatile memory functions and thus the cost and the complexity of the image processor may be reduced. Other advantages will be recognized by those or ordinary skill in the art.

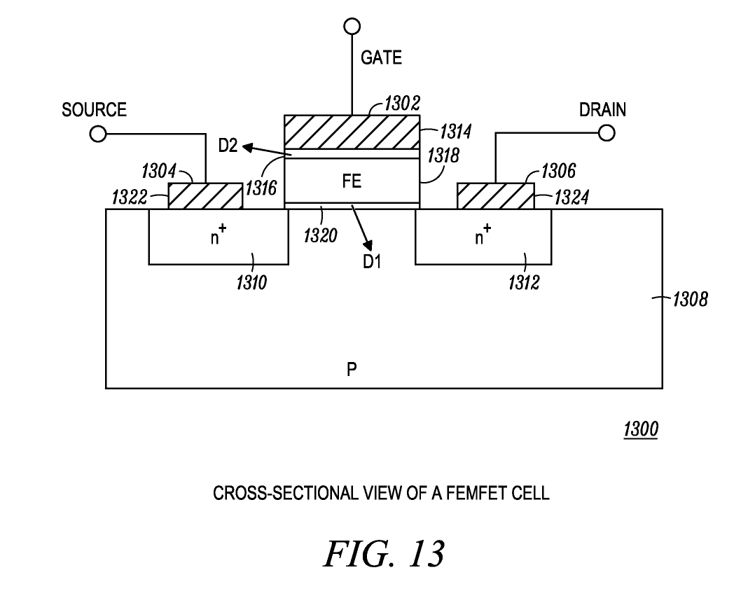

FIG. 13 illustrates one example of a cross sectional view of a CMOS ferroelectric gate field effect transistor such as the ones shown as ferroelectric elements 404, 804, and others above. As shown, the ferroelectric FET 1300 includes a gate 1302, a source 1304 and a drain 1306. Ferroelectric FET 1300 is fabricated with a p type substrate 1308 with n wells 1310 and 1312 fabricated as portions of the source 1304 and drain 1306 respectively. The gate 1302 includes a metal layer 1314. A first dielectric layer 1316, such as a silicon oxide layer, is disposed between a ferroelectric layer 1318 and the metal layer 1314. Another dielectric layer 1320 having a same or different dielectric constant than the dielectric layer 1316 is disposed on the p substrate 1308. It will be recognized that conventional fabrication techniques may be used.

As also shown, the source includes a metal layer shown as layer 1322, and similarly the drain includes a metal layer 1324. It will be recognized that although a depletion type of ferroelectric FET is shown, that any suitable type may also be used as desired. In addition, it will be recognized that any other suitable layers may be added or variations made depending upon the design requirements for a particular application.

The above detailed description of various embodiments of the invention and the examples described therein have been presented for the purposes of illustration and description only and not by limitation. It is therefore contemplated the present invention cover any and all modifications, variations, or equivalents that fall in the spirit and scope of the basic underlying principles disclosed above and claimed herein.

What is claimed is:

1. A light sensing circuit comprising:
at least one light sensing element; and
at least one ferroelectric element operatively coupled to the at least one light sensing element.

2. The circuit of claim 1 comprising:
at least one diode operatively coupled to both the at least one light sensing element and the at least one ferroelectric element and operatively responsive to control information that selectively activates the diode and causes the ferroelectric element to erase a charge stored based on light energy sensed by the light sensing element.

3. The circuit of claim 2 comprising control logic operatively coupled to the light sensing circuit, the diode, and the ferroelectric element, and operative to control the at least one ferroelectric element to erase a charge provided by the light sensing element, store a charge provided by the light sensing element, and output a charge stored by the ferroelectric element.

4. The circuit of claim 2 wherein the at least one light sensing element comprises at least one photodiode having a first terminal and a second terminal, wherein the at least one ferroelectric element comprises a ferroelectric field effect transistor having a third terminal coupled to the first terminal of the photodiode and a fourth terminal operative to produce a signal in response to light sensed by the at least one light sensing element and a fifth terminal operatively responsive to control information.

5. The circuit of claim 1 comprising at least one field effect transistor (FET) having a terminal operatively coupled to the at least one light sensing element; and
wherein the at least one ferroelectric element is operatively coupled to both the at least one light sensing element and the at least one field effect transistor.

6. The circuit of claim 5 comprising control logic, operatively coupled to the FET and the ferroelectric element, and operative to cause the ferroelectric element to erase a charge provided by the light sensing element, store a charge provided by the light sensing element, and output a charge stored by the ferroelectric element.

7. The circuit of claim 5 comprising control logic operatively coupled to the light sensing circuit and the ferroelectric element, and operative to cause the ferroelectric element to erase a charge provided by the light sensing element, store a charge provided by the light sensing element, and output a charge stored by the ferroelectric element.

8. The circuit of claim 5 wherein the at least one field effect transistor includes another terminal operatively responsive to reset/erase information.

9. A photo sensor array comprising:
a plurality of ferroelectric element based photo cells, each of the photo cells comprising at least a ferroelectric field effect transistor (FET) and a photodiode operatively coupled to the ferroelectric FET, each ferroelectric FET having a gate coupled as a reset node and a drain as an output node.

10. The photo sensor array of claim 9 wherein each of the ferroelectric element based photo cells comprises:
at least one diode operatively coupled to both the at least one light sensing element and the at least one ferroelectric FET and operatively responsive to erase control information.

11. The photo sensor array of claim 9 wherein each of the ferroelectric element based photo cells comprises:
at least one field effect transistor having a terminal operatively coupled to the at least one light sensing element; and
wherein the at least one ferroelectric FET is operatively coupled to both the at least one light sensing element and the at least one field effect transistor.

12. A photo sensor array comprising:
a first photo cell comprising:
a first light sensing element;
a first ferroelectric element operatively coupled to the first light sensing element; and
a first diode operatively coupled to both the first light sensing element and the first ferroelectric element wherein the first photo cell is operatively responsive to a first reset/erase signal; and
a second photo cell comprising:
a second light sensing element;
a second ferroelectric element operatively coupled to the second light sensing element; and
a second diode operatively coupled to both the second light sensing element and the second ferroelectric element wherein the second photo cell is operatively responsive to the first reset/erase signal;
a third photo cell comprising:
a third light sensing element;
a third ferroelectric element operatively coupled to the third light sensing element; and
a third diode operatively coupled to both the third light sensing element and the third ferroelectric element wherein the third photo sensor cell is operatively responsive to a second reset/erase signal; and
a fourth photo cell comprising:
a fourth light sensing element;
a fourth ferroelectric element operatively coupled to the fourth light sensing element; and
a fourth diode operatively coupled to both the fourth light sensing element and the fourth ferroelectric element wherein the fourth photo cell is operatively responsive to the second reset/erase signal.

13. The photo sensor array of claim 12 wherein each of the light sensing elements comprises at least one photodiode having a first terminal and a second terminal, wherein each of the corresponding ferroelectric elements comprises:
a ferroelectric field effect transistor having a third terminal coupled to the first terminal of each respective photodiode, and a fourth terminal operative to produce a signal in response to light sensed by a respective light sensing element, and a fifth terminal operatively responsive to control information.

14. The photo sensor array of claim 13 comprising control logic operatively coupled to each of the photo cells and operative to control the at least one ferroelectric element to erase a charge provided by the light sensing element, store a charge provided by the light sensing element, and output a charge stored by the ferroelectric element.

15. A photo sensor array comprising:
a first photo cell comprising:
at least a first light sensing element;
at least a first field effect transistor having a terminal operatively coupled to the at least first light sensing element; and
at least a first ferroelectric element operatively coupled to both the at least first light sensing element and the at least first field effect transistor; and
a second photo cell comprising:
at least a second light sensing element;
at least a second field effect transistor having a terminal operatively coupled to the at least second light sensing element; and
at least a second ferroelectric element operatively coupled to both the at least second light sensing element and the at least second field effect transistor;
a third photo sensor cell comprising:
at least a third light sensing element;
at least a third field effect transistor having a terminal operatively coupled to the at least third light sensing element; and
at least a third ferroelectric element operatively coupled to both the at least third light sensing element and the at least third field effect transistor; and
a fourth photo sensor cell comprising:
at least a fourth light sensing element;
at least a fourth field effect transistor having a terminal operatively coupled to the at least fourth light sensing element; and
at least a fourth ferroelectric element operatively coupled to both the at least fourth light sensing element and the at least fourth field effect transistor; and
control logic operative to control each of the ferroelectric elements to erase a charge provided by a respective light sensing element, store a charge provided by a respective light sensing element, and output a charge stored by each of the ferroelectric elements.

16. The photo sensor array of claim 15 wherein each of the ferroelectric elements comprises a CMOS ferroelectric field effect transistor.

17. A photo sensor array comprising:
a plurality of pixel cells each comprising:
a blue photo cell comprising:
at least one blue light sensing element;
at least a first field effect transistor having a terminal operatively coupled to the at least one blue light sensing element; and
at least a first ferroelectric element operatively coupled to both the at least one blue light sensing element and the at least first field effect transistor;
a red photo cell comprising:
at least one red light sensing element;
at least a second field effect transistor having a terminal operatively coupled to the at least one red light sensing element; and
at least a second ferroelectric element operatively coupled to both the at least one red light sensing element and the at least second field effect transistor; and
a green photo cell comprising:
at least one green light sensing element;
at least a third field effect transistor having a terminal operatively coupled to the at least one green light sensing element; and
at least a third ferroelectric element operatively coupled to both the at least one green light sensing element and the at least third field effect transistor.

18. The photo sensor array of claim 17 comprising control logic operative to cause each of the ferroelectric elements to erase a charge provided by a respective light sensing element, store a charge provided by a respective light sensing element, and output a charge stored by the ferroelectric element.

19. A photo sensor array comprising:
a first ferroelectric element having a first output;
a first red photodiode having a first anode and a first green photodiode having a second anode, wherein the first anode and second anode are coupled to each other and operatively coupled to the first ferroelectric element;
a first field effect transistor having a terminal operatively coupled to the first anode, the second anode, and the first ferroelectric element;
a first blue photodiode having a third anode;
a second ferroelectric element operatively coupled to the third anode and having a second output;
a second field effect transistor having a terminal operatively coupled to the third anode and to the second ferroelectric element;
a second green photodiode having a fourth anode;
a third ferroelectric element operatively coupled to the fourth anode and having a third output;
a third field effect transistor having a terminal operatively coupled to the fourth anode and to the third ferroelectric element;
a second red photodiode having a fifth anode and second blue photodiode having a sixth anode, wherein the fifth anode and the sixth anode are coupled to each other;
a fourth ferroelectric element operatively coupled to the fifth anode and the sixth anode and having a fourth output; and
a fourth field effect transistor having a terminal operatively coupled to the fifth anode and the sixth anode and to the fourth ferroelectric element.

20. The photo sensor array of claim 21 comprising control logic operative to provide a global electronic shutter operation of the photo sensor array.

21. The photo sensor array of claim 20 wherein each of the ferroelectric elements comprises a CMOS ferroelectric gate FET.

22. A method for capturing image information comprising:
generating retention control information;
storing, in a ferroelectric element, a charge representing light energy received by a light sensing element in response to the retention control information,
generating read control information to read the stored charge from the ferroelectric element; and
generating erase control information to erase the ferroelectric element after reading the stored charge in the ferroelectric element.

23. The method of claim 22 wherein generating the read control information comprises generating read control information for a corresponding plurality of ferroelectric elements arranged in a photo sensor array.

24. The method of claim 22 wherein generating erase control information comprises generating reset control information to reset the light sensing element.
